(19) United States
(12) Patent Application Publication
(10) Pub. No.: US 2018/0342628 A1
(43) Pub. Date: Nov. 29, 2018

(54) COLD-WEATHER PHOTOVOLTAIC PANEL

(71) Applicant: Shawn L. Otto, Marine on St. Croix, MN (US)

(72) Inventor: Shawn L. Otto, Marine on St. Croix, MN (US)

(21) Appl. No.: 15/988,233

(22) Filed: May 24, 2018

Related U.S. Application Data
(60) Provisional application No. 62/511,127, filed on May 25, 2017.

(51) Int. Cl. H01L 31/024; H01L 31/02; H01L 31/05

(52) U.S. Cl. CPC H01L 31/024; H01L 31/05; H01L 31/02021

(57) ABSTRACT

Aspects of the disclosure include a photovoltaic system including a photovoltaic panel. The photovoltaic panel includes a solar cell layer, a protective layer provided over a first surface of the solar cell layer, a sensor positioned on an outer surface of the protective layer, and a heater positioned on an inner surface of the protective layer. A controller can receive a signal from the sensor indicative of one or more environmental conditions on the outer surface of the protective layer, and if one or more conditions meet a predetermined condition, the controller can actuate a switch to provide electrical power to the heater to heat the protective layer. The heater can include a heating wire grid that can be aligned with gaps between solar cells in the solar cell layer to prevent occlusion of the elements from the heating wire grid.

### CROSS-REFERENCES

This application claims priority to U.S. Provisional Application No. 62/511,127 filed May 25, 2017, the content of which is hereby incorporated by reference in its entirety.

### BACKGROUND

Solar power from photovoltaic panels is a common source of renewable energy, and is often used in warm, sunny climates that take advantage of the long daylight hours and lack of accumulating precipitation. However, in cold-weather climates, when precipitation accumulates, for example, in the form of snow or ice, such accumulation on the surface of a photovoltaic panel can occlude the panel and greatly reduce the power generated by the panel. For instance, a layer of snow may reflect a significant amount of sunlight incident on a snow-covered panel, preventing the conversion of the electromagnetic radiation to usable energy. In some cold-weather climates with significant precipitation and prolonged periods of cold weather, accumulation of snow and ice can reduce or even eliminate the power generated from a photovoltaic panel for months on end, reducing the benefits and increasing the cost per unit energy generated by the panel over the course of its lifetime.

### SUMMARY

Some aspects of the disclosure are directed to photovoltaic systems including one or more heaters to prevent occlusion from accumulation in cold weather. In some embodiments, a photovoltaic system includes a photovoltaic panel that includes a solar cell layer comprising a plurality of solar cells. The solar cell layer includes a first surface for receiving electromagnetic radiation and a second surface opposite the first.

The panel further includes a protective layer positioned over the first surface of the solar cell layer having an inner surface that faces the first surface of the solar cell layer and an outer surface opposite the inner surface. A heater such as a heating wire grid can be positioned between the inner surface of the protective layer and the first surface of the solar cell layer, for example, attached to the inner surface of the protective layer. A sensor can be positioned on the outer surface of the protective layer and can be configured to output a signal representative of one or more environmental conditions on the outer surface of the protective layer.

An exemplary system can include a switch configured to selectively apply electrical power to the heater and a controller in communication with the sensor and the switch. The controller can be configured to receive a signal from the sensor indicative of one or more environmental conditions on the outer surface of the protective layer, and, if the one or more environmental conditions meet a predetermined condition, actuate the switch to apply electrical power to the heater. In some examples, the heats the protective layer.

Heating the protective layer can act to melt any cold-weather accumulations or otherwise create a water slick between the protective layer and the accumulation so that the accumulation slides off of the panel.

The heater can include a heating wire grid that can be aligned with gaps between solar cells in the solar cell layer to prevent occlusion of the elements from the heating wire grid.

### BRIEF DESCRIPTION OF THE DRAWINGS

FIG. 1 shows a schematic illustration of an exploded view of a cold-weather solar panel according to some embodiments.

FIG. 2 shows an exemplary configuration of a heating wire grid on a protective layer.

FIG. 3 is a schematic diagram illustrating the application of power to the heating wire grid in response to a signal from the one or more sensors.

FIG. 4 is a process flow diagram illustrating exemplary operation of a cold weather photovoltaic panel.

### DETAILED DESCRIPTION

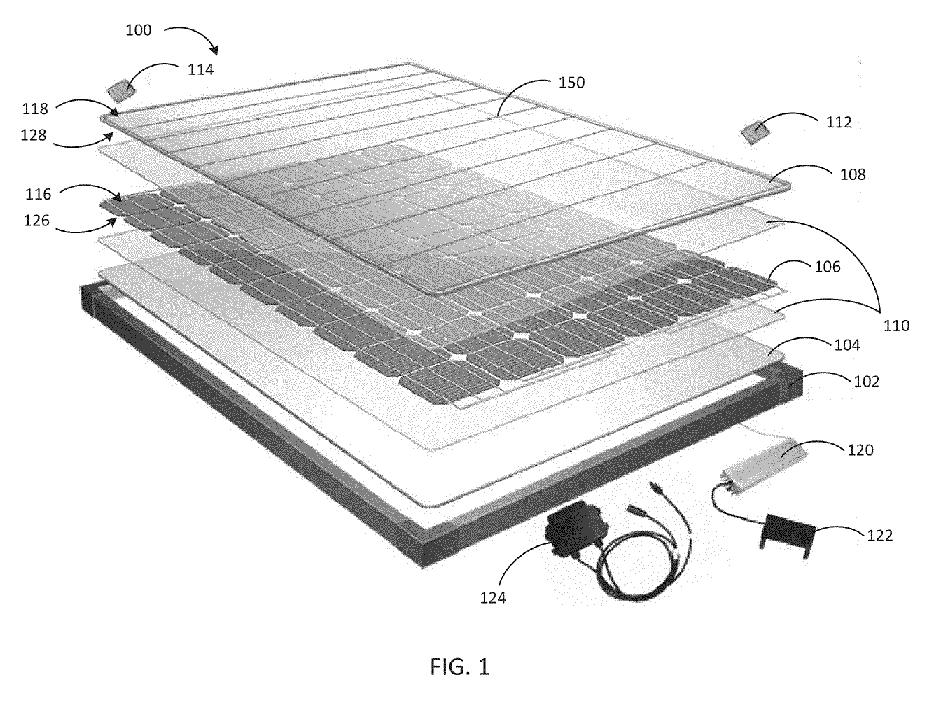

Aspects of the disclosure generally relate to designs for a cold-weather photovoltaic panel. FIG. 1 shows a schematic illustration of an exploded view of a cold-weather solar panel according to some embodiments. In some examples, the panel 100 includes a frame 102, a backing layer 104, a solar cell layer 106 and a top protective layer 108. In some examples, the solar cell layer 106 includes solar cells encapsulated between layers of an encapsulant 110, such as ethylene and vinyl acetate. Solar cell layer 106 can include a first side 116 that can be designed for receiving electromagnetic radiation and a second side 126 opposite the first 116. Protective layer 108 can be a durable and moisture-resistant material capable of protecting the solar cell layer 106 from external elements, such as impacts and/or moisture. In various embodiments, the protective layer 108 is made from a material substantially transparent to wavelengths of light to be absorbed by the solar cell layer 106, for example, the visible spectrum. In some such examples, the protective layer 108 can include glass, plastic, or any other appropriate protective material. The protective layer includes an inner surface 128 facing the first side 116 of the solar cell layer 106 and an outer surface 118 opposite the inner surface 128.

In some embodiments, the panel includes one or more sensors 112, 114 on the outer surface 118 of the protective layer 108 for detecting snow and/or ice present on the panel, or the possibility of snow and/or ice forming on the panel (e.g., on the outer surface 118 of the protective layer 108). In some examples, this is performed by sensing at least one of moisture and temperature present on the surface of the protective layer 108. In some embodiments, the protective layer 108 protects the solar cell layer 106 and other electrical components from the external environment, for instance, to keep the interior of the panel 100 dry. Accordingly, in some embodiments, the one or more sensors (e.g., 112, 114) are positioned on an outer surface of the protective layer 108 to sense temperature and/or moisture present on the outer surface of the panel. In some embodiments, a single sensor (e.g., 112 or 114) can be used on a lower corner or edge of the panel. Alternatively, a pair of sensors (e.g., 112 and 114) positioned on opposing corners enables use in any orientation.

In some embodiments, the protective layer 108 includes a heating wire grid 150 positioned thereon, for example, on the inner surface 128 of the protective layer 108. The heating wire grid 150 can be applied to the protective layer 108 in a variety of ways, such as, for example, printed or deposited onto the protective layer 108 or otherwise formed and subsequently attached to the protective layer 108 (e.g., via an adhesive). In some examples, the material of the protective layer 108 can dictate how the heating wire grid 150 is attached thereto. For example, in the case of an electrically conductive protective layer 108, the heating wire grid 150 can be attached to the protective layer 108 via an electrically insulating adhesive to prevent short circuits between portions of the grid 150 via the protective layer 108. The adhesive can be thermally conductive to promote heat transfer between heating wire grid 150 and the protective layer 108. In some examples, such an adhesive can be thermally conductive and also transparent to the wavelengths of light at which the solar cell layer 106 operates most efficiently. Exemplary materials can include polymers (e.g., polyethylene) configured to conduct heat (e.g., via a particular forming process as described in http://www.popsci.com/science/article/2010-03/new-polymer-conducts-better-metals-only-one-direction).

The heating wire grid 150 itself can comprise any of a variety of materials. In some embodiments, the heating wire grid 150 comprises an electrically conductive material such as metallic elements and/or alloys or other conductive materials such as a conductive film such that electricity applied to the heating wire grid 150 will cause the grid 150 to increase in temperature. In other examples, semiconductor or other materials capable of generating heat in response to applied electrical power can be used. In some embodiments, the heating wire grid 150 can include a transparent conductive material such as indium tin oxide (ITO) or the like can be used. In still further embodiments, conductive polymers can be used to form the heating wire grid 150.

The heating wire grid 150 can be in communication with a power source capable of providing electrical power to the heating wire grid 150 in order to heat the protective layer 108 of the solar panel 100. In some such embodiments, the heating wire grid 150 can be positioned on the underside of the protective layer 108 to be protected from external elements such as snow or rain, which can negatively impact the ability of the heating wire grid 150 to heat the protective layer 108.

When the sensor(s) 112, 114 detect snow and/or ice (or conditions for the formation thereof), a controller 120, for example, mounted on the panel backing layer and in communication with the sensor(s) 112, 114 can perform an action to prevent the build-up of snow or ice on the surface of the protective layer 108, such as closing a circuit to cause current to flow through the heating wire grid 150 to heat the protective layer 108. As the heating grid 150 is heated by the applied power, the top protective layer warms to create a water slick and the snow and/or ice on the panel slides off of the protective layer, clearing the panel. When the sensor(s) no longer sense snow and/or ice on the panel, the sensor(s) turn off and the controller opens the circuit, ceasing the application of power to the heating grid 150.

In various examples, the controller comprises one or more elements configured to receive data or signals and perform subsequent action in response to such received data or signals. Controller can be embodied as one or more components, such as one or more microcontrollers, processors, microprocessors, application specific integrated circuits (ASICs), or the like. In some examples, a system can include a memory, integral with or separate from the controller, including executable instructions for the controller to perform one or more tasks such as described herein.

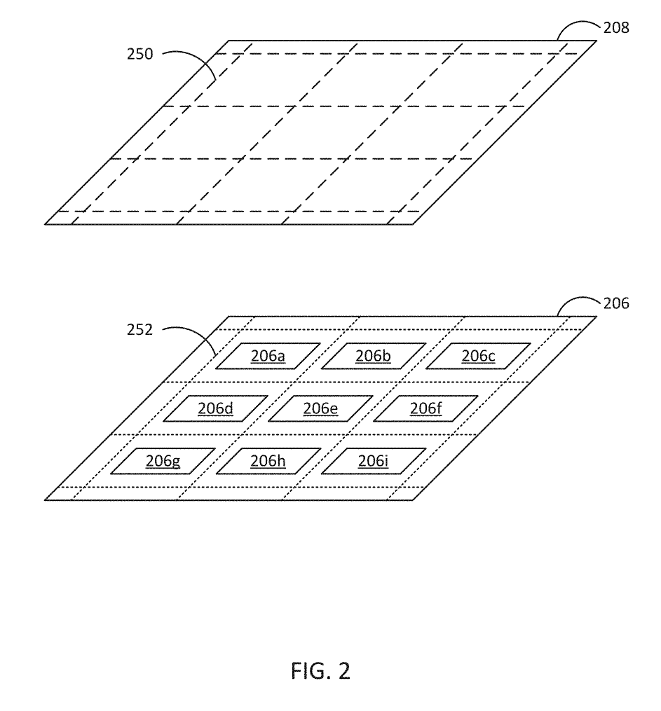

In some embodiments, the solar cell layer 106 includes a solar cell array including a grid of solar cells. In some such examples, the heating wire grid 150 of the protective layer 108 is aligned with the solar cell grid in order to reduce/prevent occlusion from the heating wire grid 150 on the solar cells. FIG. 2 shows an exemplary configuration of a heating wire grid on a protective layer. The exemplary configuration of FIG. 2 shows a section of a protective layer 208 having a heating wire grid 250 shown in broken lines disposed on the underside thereof. The section of protective layer 208 is an exemplary arbitrary portion of a protective layer 208 for use with a solar panel. It will be appreciated that the grid 250 on the protective layer 208 may be designed differently at different portions of the panel. For example, the protective layer 208 could include buss bars or other electrical connections in portions of the protective layer 208, such as at one or more edges of the layer.

FIG. 2 further includes a section of a solar cell layer 206 including a plurality of solar cells 206a-206i disposed thereon. While not shown as necessarily being connected, any of solar cells 206a-206i can be isolated or otherwise connected to one another in series, parallel, or a combination thereof as is known. Additionally, while shown as being rectangular cells arranged in a rectangular grid, any of a variety of configurations of cells 206a-206i are possible.

In some examples, the solar cells 206a-206i are arranged on the solar cell layer 206 so that gaps exist between cells 206a-206i. When protective layer 208 and solar cell layer 206 are brought close together, such as in the construction of the solar panel, the heating wire grid 250 may cast a shadow 252 (shown in phantom) on to the solar cell layer 206. Shadows can include areas in which visible light is blocked (e.g., by a non-transparent metallic heating wire grid 250) from reaching the solar cell layer 206. In other examples, the heating wire grid 250 can block light at other, non-visible wavelengths (e.g., infrared and/or ultraviolet wavelengths) from reaching the solar cell layer 206 (e.g., a transparent conductive heating wire grid 250 may absorb non-visible wavelengths of light). In some embodiments, the material used for the heating wire grid can be selected to have minimal absorption across a wavelength or plurality of wavelengths of light at which the solar cells 206a-206i operate most efficiently.

Additionally or alternatively, in some embodiments, the heating wire grid 250 and solar cells 206a-206i are constructed such that, when the protective layer 208 and solar cell layer 206 are brought together, the heating wire grid 250 is aligned with the gaps between solar cells 206a-206i. Thus, in some such embodiments, shadows 252 on the solar cell layer caused by the heating wires fall between the solar cells to minimize the effect on the shadows on cell performance.

In some examples, the heating wire grid 250 is close enough to the solar cell layer 206 when the panel is constructed so that the shadow 252 of the grid 250 does not substantially move across the surface of the solar cell layer 206. Additionally or alternatively, the grid 250 may be positioned biased to a particular direction relative to the solar cells 206a-206i in order to compensate for common sun angles (e.g., the grid 250 is offset to the south from being directly over spaces between cells 206a-206i in northern hemisphere installations to compensate for the sun in the southern sky) and/or environmental factors. Various offsets are possible and can be constructed for individual implementations. In some examples, the protective layer 208 and associated heating wire grid 250 are adjustable relative to the solar cell layer 206 to allow a user to manually adjust the position of the grid 250 above the solar cells 206a-206i.

In some embodiments, the heating wire grid 250 can be positioned so that shadows from the grid 250 are over additional or alternative parts of the panel. For instance, in some examples, wire traces on the solar cells 206a-206i for providing electrical connections to various panel components may already shade portions of the cells. In some such embodiments, the heating wire grid 250 can be positioned to align with such elements. In general, the heating wire grid 250 can be positioned on the protective layer 208 to align favorably with solar cells 206a-206i on the solar cell layer 206. In some embodiments, the protective layer 208 can be adjustable relative to the solar cell layer 206 for customizable alignment. It will be appreciated that, while referred to herein as a heating wire grid 250, the heating wire is not limited to a square or rectangular grid. Rather, the heating wire can be arranged in any pattern to favorably shade certain regions of the solar cell layer 206 and/or to provide adequate heating to the protective layer 208.

Additionally or alternatively, the grid 250 may include a plurality of conductors that do not intersect of otherwise contact one another. For instance, with reference to FIG. 2, in an exemplary embodiment, grid wires may be present between rows of cells (e.g., between cell 206a and cell 206d) but not columns (e.g., between cell 206a and cell 206b). In some such examples, the heating wire grid 250 includes a plurality of conductors arranged in parallel, e.g., between common buss bars on opposing ends of the protective layer 208. In some embodiments, the heating wire grid 250 includes intersecting conductor traces (as shown in FIG. 2). In some such embodiments, one or more of the conductors are electrically isolated from one another at the intersection point of their respective traces. In various embodiments, different conductors of the heating wire grid can be arranged in series, parallel, or a combination thereof.

In some embodiments, when the controller detects the presence of or favorable conditions for snow and/or ice, the controller acts to close a circuit to cause power to flow through the heating wire grid. In some examples, when the circuit is closed, a cable tap draws power from the output circuitry of the solar panel (e.g., between an inverter and an output cable in AC systems or between the junction box and downstream DC wiring in DC systems). In some such examples, the controller transforms the power drawn from the cable tap to a desirable level of power for heating the grid (e.g., a 12 volt DC signal).

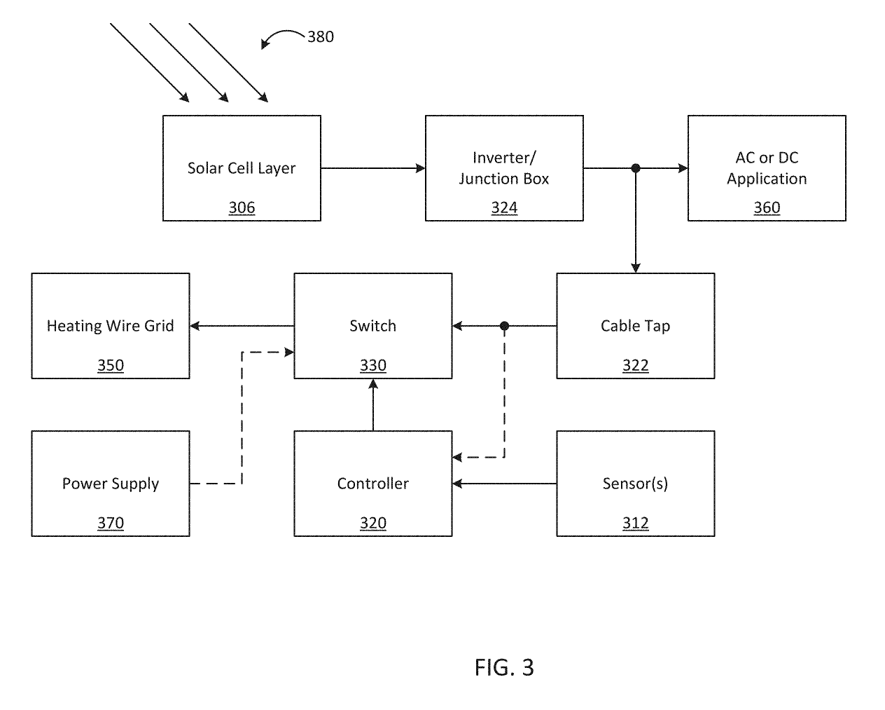

FIG. 3 is a schematic diagram illustrating the application of power to the heating wire grid in response to a signal from the one or more sensors. In the illustrated example, a solar cell panel 306 receives electromagnetic radiation 380 (e.g., from the sun) and converts the electromagnetic radiation into electrical energy, which is generally provided to an inverter and/or a junction box 324. Electrical energy from the inverter and/or junction box 324 is generally configured to provide electrical energy to an AC (inverter) or a DC (junction box, no inverter) application 360. A cable tap 322 can be positioned in the circuit in order to draw electrical power from the output of the inverter and/or junction box 324.

One or more sensor 312 as described elsewhere herein are configured to detect the presence of and/or conditions favorable for the formation of snow and/or ice (e.g., temperature and/or moisture sensors). The one or more sensor 312 are in communication with a controller 320 configured to control operation of the switch 330. The controller can be configured such that, when a signal received from the one or more sensors 312 satisfies a predetermined condition, the controller acts to close the switch 330 to apply electrical power to the heating wire grid 350. In some examples, the predetermined condition comprises a certain temperature, a certain amount of moisture, or a combination thereof.

Once the controller 320 closes the switch 330, electrical power is directed to the heating wire grid 350 to prevent the build-up of snow and/or ice on the surface of the panel (e.g., on the protective layer. Power can be applied to the heating wire grid 350 from the switch in a variety of ways. In some embodiments, the switch 330 connects the cable tap 322 to the heating wire grid 350 so that power is applied to the grid 350 from the cable tap 322. In various embodiments, the cable tap 322 can receive AC or DC power from the solar panel circuitry. In some embodiments, the AC or DC power is applied to the heating wire grid 350. Alternatively, in some examples, the cable tap 322 and/or switch 330 include circuitry (e.g., rectification circuitry, transformers, voltage limiters, etc.) to modulate the signal coming into the cable tap 322 to a desired output signal for applying to the heating wire grid 350. In some such examples, such circuitry is configured to apply a constant DC voltage to the heating wire grid 350.

In alternative embodiments, instead of feeding directly to the heating wire grid 350 via switch 330, the output of the cable tap 322 is received by the controller 320 (e.g., shown via broken line in FIG. 3). In some such embodiments, the controller 320 is configured to transform the signal output from the cable tap 322 to a desirable signal for application to the heating wire grid 350. Thus, the controller 320 can be configured so that, when receiving a predetermined signal from the one or more sensors 312, the controller 320 closes switch 330 and an output from the controller 320 is provided via the switch to the heating wire grid 350.

Additionally or alternatively, the switch 330 can be in communication with a separate power supply 370 for providing desired power to the heating wire grid 350, for example, if power is unavailable from the cable tap 322.

In various embodiments, a solar cell such as described herein could be implemented as a single packaged panel including a cable tap, a frame, a backing layer with mounted controller, an encapsulated solar cell layer, and a top protective layer having heating grid and one or more sensors for sensing snow and/or ice. Alternatively, an after-market panel modification option includes a controller, a cable tap, a top protective layer with a heating grid and one or more sensors for sensing snow and/or ice can be designed and sold as a modification kit to install over existing panels. For example, the grid printed on the top protective layer can be designed according to the design of the existing panel so that the grid aligns with gaps in the solar cells on the solar layer.

An exemplary implementation of a cold weather photovoltaic panel functions as described below, wherein the panel assembly senses the presence of snow or ice, warms top panel protective layer via heater to create a water slick. Snow and ice slides off the panel clearing panel. When snow or ice no longer present, the panel turns off the heater. This increases solar panel performance by keeping panel clear of snow and ice that otherwise occlude panel and reduce output.

During exemplary operation, if a sensor (e.g., a snow and/or ice sensor) interpolates presence of both low temp and moisture, a controller closes a circuit. A controller can be configured to measure a line current and transforms it to 12 VDC. When snow & ice sensor closed, the controller delivers 12 VDC current to a heating grid painted on the underside of a top protective layer. The heating grid can be aligned with gaps between photovoltaic cells to prevent occlusion. A cable tap can be inserted into the system (e.g., between a microinverter and an output, e.g., a 250 VAC cable, in AC systems or between panel j-box DC output cables and DC wiring DC systems) to provide electrical power to the heating grid.

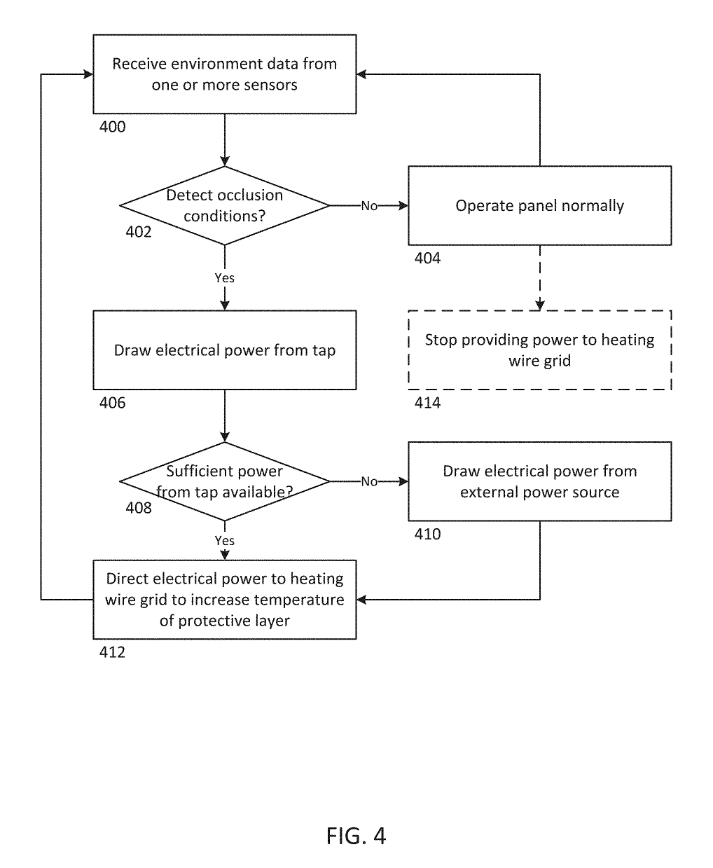

FIG. 4 is a process flow diagram illustrating exemplary operation of a cold weather photovoltaic panel. In some example, the process of FIG. 4 can be executed by a system controller (e.g., 320). The process of FIG. 4 includes receiving environment data from one or more sensors (400). Such environment data can include, for instance, temperature data and moisture data. The process further includes determining if occlusion conditions are present (402), for example, based on the received environment data. In an exemplary embodiment, occlusion conditions includes a combination of a temperature measurement being below freezing and the presence of moisture, increasing the likelihood that the moisture could accumulate as ice or snow on the surface of the panel.

If occlusion conditions are not detected, then panel operation continues normally (404). However, if occlusion conditions are detected, the panel can proceed to draw power from a cable tap (e.g., from the electrical output of the photovoltaic system) to apply to the heating grid (406). In some examples, the process includes determining if sufficient power is available from the cable tap (408) to adequately power the heating grid. If not, the process can include drawing electrical power from an external power source (410). Electrical power (e.g., from the cable tap and/or the external power source) is directed to the heating wire grid to increase the temperature of the protective layer of the panel (412).

As power is directed to the heating wire grid, the process repeats in which the environment data from the one or more sensors is received and analyzed to detect one or more occlusion conditions, if occlusion conditions are still detected, then power is continued to be applied to the grid. However, if occlusion conditions are no longer detected, then the panel can resume normal operation (404) and power application to the heating wire grid can be stopped (414).

In some examples, the occlusion conditions required to initially start providing power to the heating wire grid are the same occlusion conditions that, once such conditions are no longer detected, cause power to stop being applied to the heating wire grid. In other examples, different conditions or combinations of conditions lead to the stopping of power application to the heating wire grid than were required to start applying the power. For instance, in an exemplary embodiment, a combination of sufficiently low temperatures and the presence of moisture triggers the application of power to the heating grid, and power is no longer applied to the heating grid only once moisture is no longer detected, independent of how a measured temperature progresses.

It will be appreciated that in various examples, steps in the process of FIG. 4 may be permuted or omitted. For instance, in some examples, steps 408 and 410 may be omitted, and only power from the cable tap is provided to the heating grid.

Various embodiments have been described. It will be appreciated that various suitable alternatives are possible and are within the scope of this disclosure. For example, heating grid could be replaced or supplemented by one or more additional or alternative heaters, such as a solid layer sheet heater. Such a sheet heater could be made from a substantially transparent material to the wavelengths of light to which the solar cells are most sensitive. In some examples, the sheet heater can include a conductive film placed on the inner surface (e.g., 128) of the protective layer (e.g., 108).

1. A photovoltaic system comprising:
a photovoltaic panel including:
a solar cell layer comprising a plurality of solar cells, the solar cell layer having a first surface for receiving electromagnetic radiation and a second surface opposite the first;
a protective layer provided over the first surface of the solar cell layer, the protective layer having an inner surface that faces the first surface of the solar cell layer and an outer surface opposite the inner surface;
a sensor positioned on the outer surface of the protective layer, the sensor being configured to output a signal representative of one or more environmental conditions on the outer surface of the protective layer; and
a heating wire grid positioned between the inner surface of the protective layer and the first surface of the solar cell layer;
a switch configured to selectively apply electrical power to the heating wire grid; and
a controller in communication with the sensor and the switch, the controller being configured to:
receive a signal from the sensor indicative of one or more environmental conditions on the outer surface of the protective layer; and
if the one or more environmental conditions meet a predetermined condition, actuate the switch to apply electrical power to the heating wire grid to heat the protective layer.

2. The system of claim 1, wherein
the plurality of solar cells of the solar cell layer are arranged into a grid pattern such that a gap exists between each of the plurality of solar cells; and
the heating wire grid is positioned such that the heating wire grid generally aligns with the gaps between the plurality of solar cells.

3. The system of claim 1, wherein the heating wire grid comprises a conductive or semiconductive material attached to the protective layer.

4. The system of claim 3, wherein the heating wire grid is attached to the protective layer via an electrically insulating, thermally conducting material.

5. The system of claim 1, wherein the signal from the sensor corresponds to a detected temperature and/or amount of moisture on the outer surface of the protective layer, and wherein the controller is configured to actuate the switch to apply electrical power to the heating wire grid in the event that:
the temperature is below a predetermined value;
the amount of moisture is above a predetermined value; or
the temperature is below a predetermined value and the amount of moisture is above a predetermined value.

6. The system of claim 1, further comprising
an inverter and/or junction box in communication with the solar cell layer and configured to output electrical power based on electrical power received from the solar cell layer; and
a cable tap in electrical communication with the inverter and/or junction box and the switch, the cable tap being configured to draw electrical power from the inverter and/or junction box and direct power to the heating wire grid via the switch when the switch is closed by the controller.

7. The system of claim 6, further comprising an external power supply in communication with the switch, and wherein the controller is configured to cause the switch to provide electrical power to the heating wire grid when power from the cable tap is unavailable or insufficient.

8. The system of claim 1, wherein the sensor is positioned in a corner or along an edge of the protective layer.

9. The system of claim 9, wherein the sensor comprises a first sensor positioned in a first corner of the protective layer and a second sensor positioned in a second corner of the protective layer, the second corner being opposite the first corner.

10. The system of claim 1, wherein the protective layer comprises glass or plastic.

11. The system of claim 1, wherein the heating wire grid comprises a transparent material.

12. A photovoltaic system comprising:
a photovoltaic panel including:
a solar cell layer comprising a plurality of solar cells, the solar cell layer having a first surface for receiving electromagnetic radiation and a second surface opposite the first;
a protective layer provided over the first surface of the solar cell layer, the protective layer having an inner surface that faces the first surface of the solar cell layer and an outer surface opposite the inner surface;
a sensor positioned on the outer surface of the protective layer, the sensor being configured to output a signal representative of one or more environmental conditions on the outer surface of the protective layer; and
a heater positioned between the inner surface of the protective layer and the first surface of the solar cell layer; and
a controller in communication with the sensor and the switch, the controller being configured to:
receive a signal from the sensor indicative of one or more environmental conditions on the outer surface of the protective layer; and
if the one or more environmental conditions meet a predetermined condition, apply electrical power to the heater to heat the protective layer.
